(19) United States
(12) Patent Application Publication
(10) Pub. No.: US 2026/0123067 A1
(43) Pub. Date: Apr. 30, 2026

(54) RADIATION DETECTOR AND MANUFACTURING METHOD OF RADIATION DETECTOR

(71) Applicant: FUJIFILM Corporation, Tokyo (JP)

(72) Inventors: Ryo TANAKA, Tokyo (JP); Masafumi ONOUCHI, Tokyo (JP); Tatsuhiko HAYASHI, Tokyo (JP)

(73) Assignee: FUJIFILM Corporation, Tokyo (JP)

(21) Appl. No.: 19/366,602

(22) Filed: Oct. 23, 2025

(30) Foreign Application Priority Data
Oct. 30, 2024 (JP) 2024-190921

(51) Int. Cl. H10F 39/18; H10F 39/00

(52) U.S. Cl. CPC H10F 39/1898; H10F 39/014

(57) ABSTRACT

A radiation detector includes a plurality of detection elements each including a plurality of pixels for detecting radiation. A manufacturing method of the radiation detector includes joining, in a state in which a detection surface, on which radiation is incident, of each of the plurality of detection elements is in contact with a first reference surface, a back surface of each of the plurality of detection elements on a side opposite to the detection surface to a fixed plate via an adhesive.

### CROSS-REFERENCE TO RELATED APPLICATION

The present application claims priority under 35 U.S.C. § 119 to Japanese Patent Application No. 2024-190921 filed on Oct. 30, 2024. The above application is hereby expressly incorporated by reference, in its entirety, into the present application.

### BACKGROUND

### 1. Technical Field

The technology of the present disclosure relates to a radiation detector and a manufacturing method of a radiation detector.

### 2. Description of the Related Art

The following technologies are known as technologies related to radiation detectors. For example, JP2015-138008A discloses a planar detector including a plurality of rectangular photoelectric conversion element substrates in which a plurality of photoelectric conversion elements are arranged, a base that supports the plurality of photoelectric conversion element substrates on a first surface, and a scintillator that is provided on a surface of the photoelectric conversion element substrate on a side opposite to the base and that converts radiation into light that can be sensed by the photoelectric conversion element.

JP1990-151789A (JP-H02-151789) discloses a multi-element radiation detector including an element block having a phosphor element, a photoelectric conversion element provided corresponding to the phosphor element, and an isolation plate provided between the phosphor element and the photoelectric conversion element, a substrate on which the element block is mounted, and a fixing frame for fixing the substrate, in which the substrate is fixed to the fixing frame with an upper surface of the substrate as a reference.

### SUMMARY

It is conceivable to configure a medical radiation detector, such as a CT apparatus by connecting a plurality of detection elements in order to widen an imaging range. The detection element includes a plurality of pixels arranged in a lattice to detect radiation (X-ray photons). In a case in which the detection elements are simply arranged, dimensional errors are accumulated, which may result in the deterioration of the image quality of the radiation image captured using the radiation detector. In addition, height positions of detection surfaces on which the radiation is incident become uneven, which may result in the deterioration of the image quality of the radiation image.

The technology of the present disclosure has been made in view of the above-described points, and an object thereof is to align height positions of detection surfaces on which radiation is incident, in a case in which a radiation detector is configured by combining a plurality of detection elements.

The technology of the present disclosure relates to a manufacturing method of a radiation detector including a plurality of detection elements each including a plurality of pixels for detecting radiation, the manufacturing method comprising: joining, in a state in which a detection surface, on which radiation is incident, of each of the plurality of detection elements is in contact with a first reference surface, a back surface of each of the plurality of detection elements on a side opposite to the detection surface to a fixed plate via an adhesive.

The adhesive may have a thickness profile in accordance with a thickness variation of the plurality of detection elements.

A laminate including the plurality of detection elements, the adhesive, and the fixed plate may be interposed between the first reference surface and a second reference surface of which a distance from the first reference surface is fixed.

The first reference surface may be brought into contact with the detection surfaces, which face downward in a vertical direction, of the plurality of detection elements.

Each of the plurality of detection elements may have a first side and a second side intersecting the first side, and the plurality of detection elements that line up along a direction of the first side and a direction of the second side may be joined to the fixed plate.

A ratio C/T of thermal conductivity C of the adhesive to a thickness T of the adhesive may be equal to or greater than a threshold value.

The plurality of detection elements may form a unit, and a plurality of the units may be combined. A direction of the detection surface may differ for each unit.

It is preferable that a material of the fixed plate is determined in consideration of rigidity. Further, it is preferable that a material of the fixed plate is determined in consideration of thermal conductivity.

The technology of the present disclosure relates to a radiation detector comprising: a plurality of detection elements each including a plurality of pixels for detecting radiation; and a fixed plate joined to back surfaces of the plurality of detection elements on a side opposite to detection surfaces on which the radiation is incident, via an adhesive, in which the detection surface of each of the plurality of detection elements extends in the same plane.

The adhesive may have a thickness profile in accordance with a thickness variation of the plurality of detection elements.

According to the technology of the present disclosure, in a case in which the plurality of detection elements are combined to constitute the radiation detector, it is possible to align the height positions of the detection surfaces on which the radiation is incident.

### BRIEF DESCRIPTION OF THE DRAWINGS

Exemplary embodiments according to the technique of the present disclosure will be described in detail based on the following figures, wherein:

FIG. 1 is a plan view showing an example of a configuration of a radiation detector according to an embodiment of the technology of the present disclosure;

FIG. 2 is a cross-sectional view taken along line 2-2 in FIG. 1;

FIG. 3 is a cross-sectional view showing an example of a configuration of a detection element constituting the radiation detector according to the embodiment of the technology of the present disclosure;

FIG. 4A is a plan view showing an example of a manufacturing method of the radiation detector according to the embodiment of the technology of the present disclosure;

FIG. 4B is a plan view showing an example of the manufacturing method of the radiation detector according to the embodiment of the technology of the present disclosure;

FIG. 4C is a plan view showing an example of the manufacturing method of the radiation detector according to the embodiment of the technology of the present disclosure;

FIG. 4D is a plan view showing an example of the manufacturing method of the radiation detector according to the embodiment of the technology of the present disclosure;

FIG. 5A is a plan view showing an example of the manufacturing method of the radiation detector according to the embodiment of the technology of the present disclosure;

FIG. 5B is a plan view showing an example of the manufacturing method of the radiation detector according to the embodiment of the technology of the present disclosure;

FIG. 5C is a plan view showing an example of the manufacturing method of the radiation detector according to the embodiment of the technology of the present disclosure;

FIG. 5D is a plan view showing an example of the manufacturing method of the radiation detector according to the embodiment of the technology of the present disclosure;

FIG. 6A is a view showing an example of a step of joining a plurality of detection elements to a fixed plate according to the embodiment of the technology of the present disclosure;

FIG. 6B is a view showing an example of the step of joining the plurality of detection elements to the fixed plate according to the embodiment of the technology of the present disclosure;

FIG. 6C is a view showing an example of the step of joining the plurality of detection elements to the fixed plate according to the embodiment of the technology of the present disclosure;

FIG. 7 is a cross-sectional view showing a heat dissipation path of the radiation detector according to the embodiment of the technology of the present disclosure;

FIG. 8 is a perspective view showing an example of an arrangement form of the plurality of detection elements;

FIG. 9 is a cross-sectional view showing an example of a configuration of a radiation detector according to a comparative example;

FIG. 10A is a cross-sectional view schematically showing an example of a configuration of a typical CT apparatus;

FIG. 10B is a cross-sectional view schematically showing an example of a configuration of a WDCT apparatus.

FIG. 11 is a cross-sectional view showing overlapping incidence of radiation in a detection element;

FIG. 12 is a perspective view of a radiation detector having a three-surface structure according to the embodiment of the technology of the present disclosure;

FIG. 13 is a perspective view showing an example of a configuration of a unit consisting of the plurality of detection elements; and

FIG. 14 is a perspective view of the radiation detector having the three-surface structure according to the embodiment of the technology of the present disclosure.

### DETAILED DESCRIPTION

Hereinafter, an example of an embodiment of the technology of the present disclosure will be described with reference to the drawings. It should be noted that the same or equivalent components and portions in the drawings are denoted by the same reference numerals, and the overlapping description will be omitted.

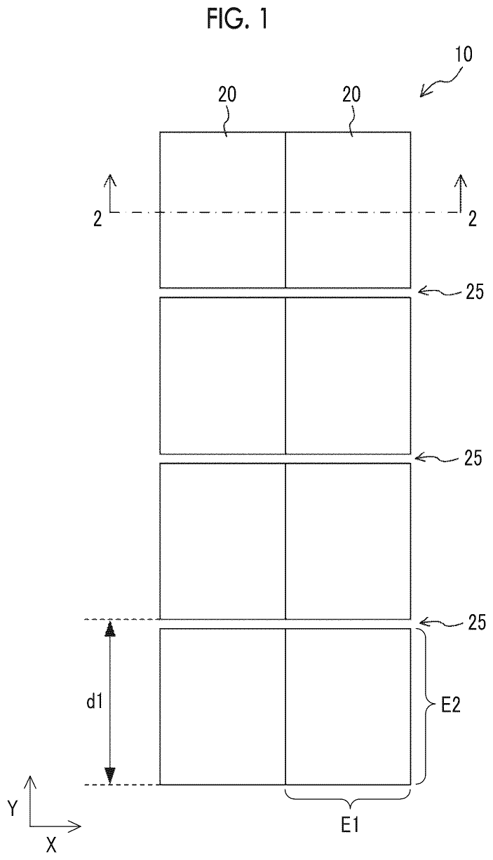

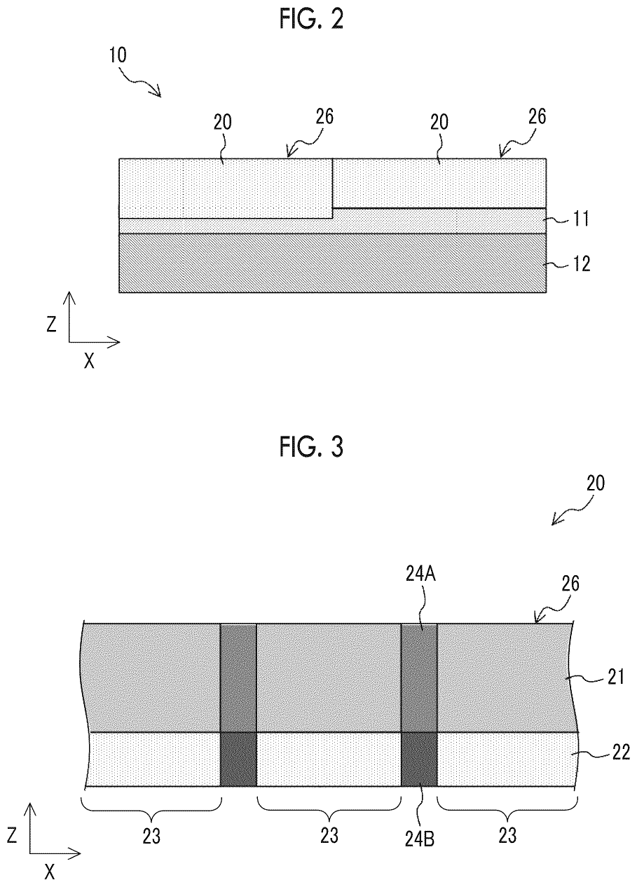

FIG. 1 is a plan view showing an example of a configuration of a radiation detector 10 according to the embodiment of the technology of the present disclosure. FIG. 2 is a cross-sectional view taken along line 2-2 in FIG. 1. FIG. 3 is a cross-sectional view showing an example of a configuration of a detection element 20 constituting the radiation detector 10.

The radiation detector 10 includes a plurality of detection elements 20. The detection element 20 has a plurality of pixels 23 that are arranged in a lattice and that detect radiation (X-ray photons). As shown in FIG. 3, the plurality of pixels 23 each include a scintillator 21 and a light-receiving element 22. The scintillator 21 is laminated on the light-receiving element 22. The radiation (X-ray photons) is incident from a side of the scintillator 21. That is, in the detection element 20, a surface of the scintillator 21 is a detection surface (light-receiving surface) 26 for radiation. The light-receiving element 22 is, for example, a photodiode.

The radiation incident on the detection surface 26 is converted into visible light by the scintillator 21. The visible light is converted into an electrical signal by the light-receiving element 22. The plurality of pixels 23 are separated from each other by a separation region 24A and a separation region 24B, and the electrical signal (pixel value) is generated for each pixel. The separation regions 24A provided in a layer of the scintillator 21 are made of, for example, a light-reflective material such as titanium dioxide. As a result, it is possible to confine the visible light, which is generated in a certain pixel, in the pixel. The separation region 24B provided in a layer of the light-receiving element 22 is made of a semiconductor or an insulator. The electrical signals for each pixel are electrically insulated and separated by the separation region 24B.

As shown in FIG. 1, the detection element 20 has a rectangular outer shape, including a side E1 and a side E2, in plan view. The radiation detector 10 is configured by arranging a plurality of detection elements 20 to line up along the side E1 and the side E2. In the present specification and the drawings, a direction along the side E1 will be referred to as an X direction, a direction along the side E2 will be referred to as a Y direction, and a thickness direction of the detection element 20 will be referred to as a Z direction. Dimensions of the side E1 and the side E2 are, for example, 10 mm to 50 mm.

FIG. 1 shows an example of a configuration in which two detection elements 20 are arranged to line up along a direction of the side E1 (X direction) and four detection elements 20 are arranged to line up along a direction of the side E2 (Y direction). The number of arranged detection elements 20 in each direction is not limited to the example shown in FIG. 1, and can be determined as appropriate.

A gap 25 is provided between the detection elements 20 that line up along a direction of the side E2 (Y direction), which is a direction in which the number of arranged detection elements 20 is relatively large. A dimension of the gap 25 is adjusted such that a distance between the sides E1 of the detection elements 20 that line up along the direction of the side E2 (Y direction) is a predetermined distance d1. The detection elements 20 are manufactured with the dimensions of the side E1 and the side E2 each having errors. By adjusting the dimension of the gap 25 as described above, it is possible to absorb the dimensional error of the side E2 by the gap 25. Accordingly, even in a case in which the plurality of detection elements 20 are arranged to line up along the direction of the side E2 (Y direction), it is possible to avoid the accumulation of the dimensional errors of the side E2. The dimension of the gap 25 provided for each connection portion of the detection element 20 changes in accordance with the dimensional error of the side E2 of the detection element 20. That is, the dimension of the gap 25 may differ for each connection portion of the detection element 20.

Meanwhile, since the number of arranged detection elements 20 in the direction of the side E1 (X direction) is small, the cumulative dimension errors of the side E1 are acceptable. Therefore, it is not necessary to provide a gap between the detection elements 20 that line up along the direction of the side E1 (X direction).

As shown in FIG. 2, the plurality of detection elements 20 are joined to the fixed plate 12 while maintaining the above-described arrangement form. A back surface of the detection element 20 on a side opposite to the detection surface 26 is joined to the fixed plate 12 via an adhesive 11. The plurality of detection elements 20 are mounted on the fixed plate 12 such that the respective detection surfaces 26 extend in the same plane (that is, the height positions of the detection surfaces 26 are aligned). A thickness variation of the plurality of detection elements 20 is absorbed by the adhesive 11. Accordingly, the adhesive 11 has a thickness profile in accordance with the thickness variation of the plurality of detection elements 20.

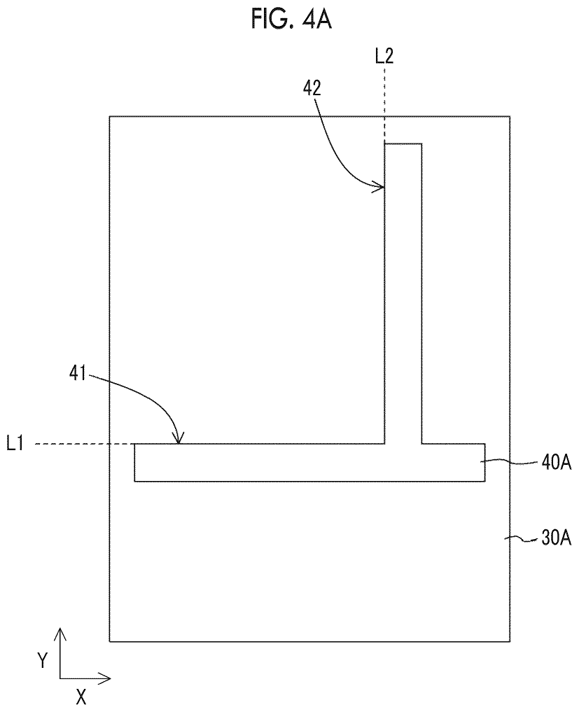

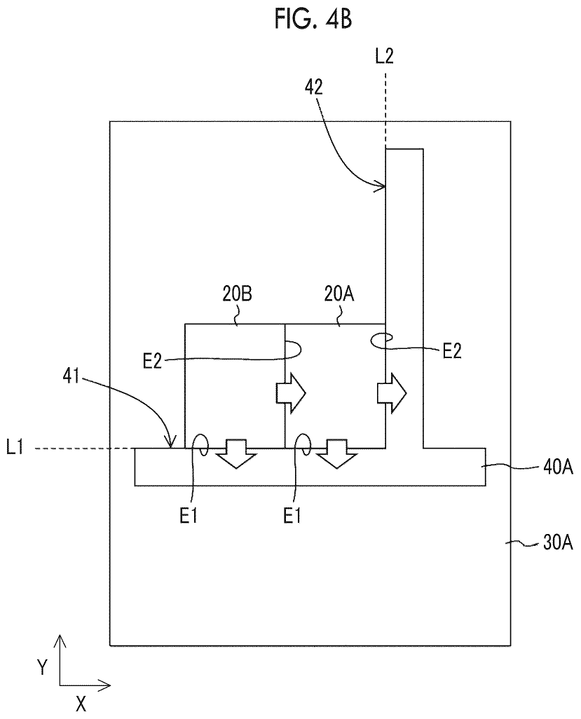

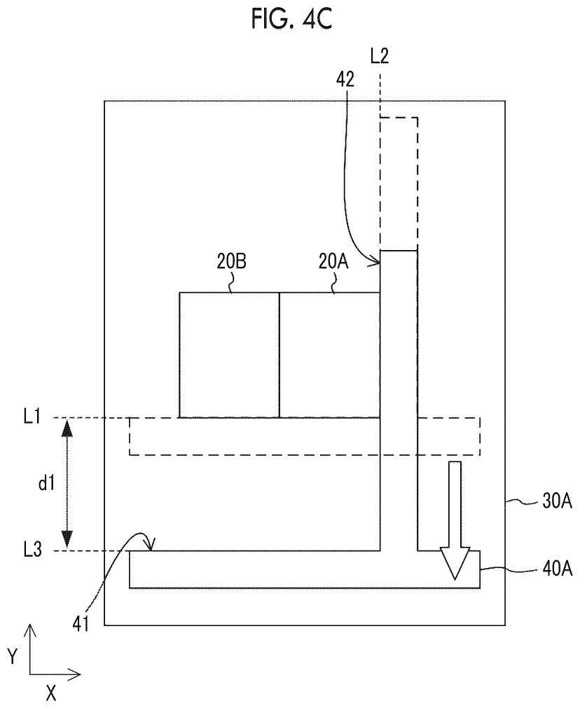

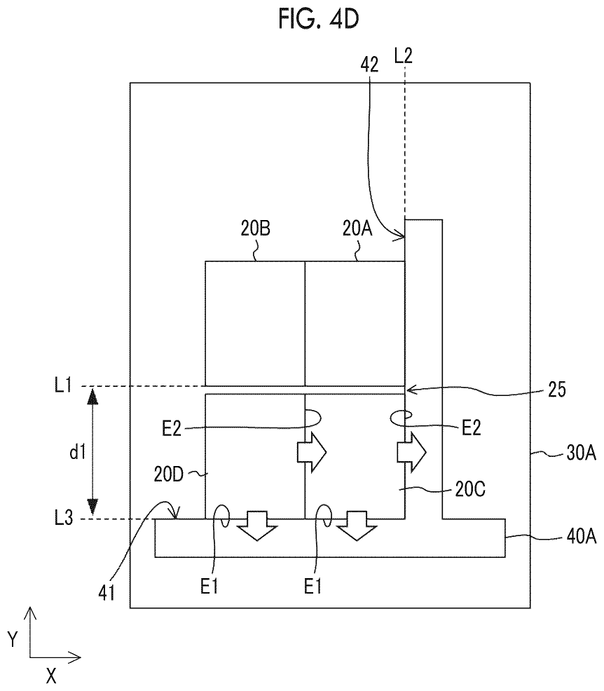

Hereinafter, a manufacturing method of the radiation detector 10 will be described. FIGS. 4A, 4B, 4C, and 4D are plan views showing an example of the manufacturing method of the radiation detector 10.

The plurality of detection elements are arranged by using a surface plate 30A and a reference plate 40A (FIG. 4A). The surface plate 30A has a flat surface as a reference surface. The reference plate 40A is disposed on a surface of the surface plate 30A. The reference plate 40A is a T-shaped or L-shaped ruler, and has a side surface 41 that defines a straight line that extends in the X direction and a side surface 42 that defines a straight line that extends in the Y direction. The straight line defined by the side surface 41 will be referred to as a first reference line L1, and the straight line defined by the side surface 42 will be referred to as a second reference line L2.

As shown in FIG. 4B, on the surface plate 30A, the side E1 of each of the detection elements 20A and 20B is brought into contact with the side surface 41 of the reference plate 40A. That is, the side E1 of each of the detection elements 20A and 20B is disposed on the first reference line L1. Further, the side E2 of the detection element 20A is brought into contact with the side surface 42 of the reference plate 40A. That is, the side E2 of the detection element 20A is disposed on the second reference line L2. Further, the side E2 of the detection element 20B is brought into contact with the detection element 20A. As a result, the detection elements 20A and 20B line up along the direction of the side E1 (X direction) in a state in which the sides E1 are aligned. The detection elements 20A and 20B are arranged on the surface plate 30A in a direction (that is, in a direction facing downward) in which the detection surface on which the radiation is incident is in contact with the surface of the surface plate 30A.

Next, as shown in FIG. 4C, the reference plate 40A is moved in the direction of the side E2 (Y direction) by the distance d1 in a state in which the detection elements 20A and 20B are stationary on the surface plate 30A. The straight line defined by the side surface 41 of the reference plate 40A after the movement will be referred to as a third reference line L3. The third reference line L3 is disposed at a position spaced from the first reference line L1 by the distance d1.

Next, as shown in FIG. 4D, the side E1 of each of the detection elements 20C and 20D is brought into contact with the side surface 41 of the reference plate 40A after the movement. That is, the side E1 of each of the detection elements 20C and 20D is disposed on the third reference line L3. Further, the side E2 of the detection element 20C is brought into contact with the side surface 42 of the reference plate 40A. That is, the side E2 of the detection element 20C is disposed on the second reference line L2. Further, the side E2 of the detection element 20D is brought into contact with the detection element 20C. As a result, the detection elements 20C and 20D line up along the direction of the side E1 (X direction) in a state in which the sides E1 are aligned. In addition, the detection element 20A and the detection element 20C line up along the direction of the side E2 (Y direction) in a state in which the sides E2 are aligned. The detection elements 20C and 20D are arranged on the surface plate 30A in a direction (that is, in a direction facing downward) in which the detection surface on which the radiation is incident is in contact with the surface of the surface plate 30A.

A distance between the sides E1 of the detection elements 20A and 20B and the sides E1 of the detection elements 20C and 20D is d1, and the gap 25 is formed between the detection elements 20A and 20B and the detection elements 20C and 20D. The dimension of the gap 25 is adjusted such that the distance between the sides E1 is d1. The dimensional error of the side E2 of each of the detection elements is absorbed by the gap 25.

Hereinafter, the 2×4 arrangement form shown in FIG. 1 can be formed by repeating the process of moving the reference plate 40A in the direction of the side E2 (Y direction) by the distance d1 and arranging the other two detection elements in the same manner as described above.

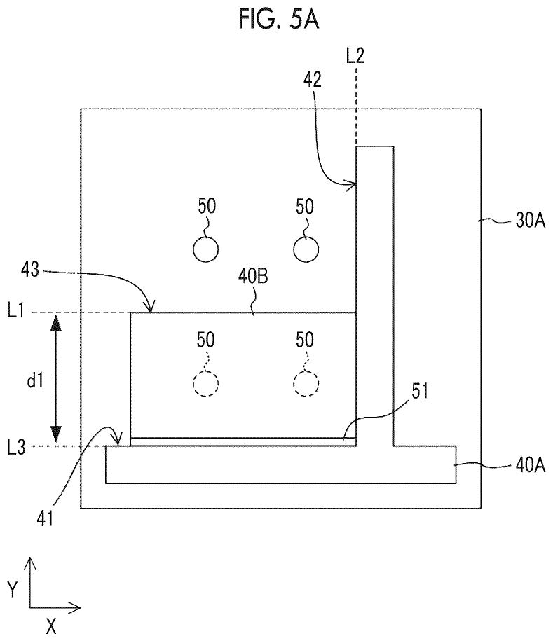

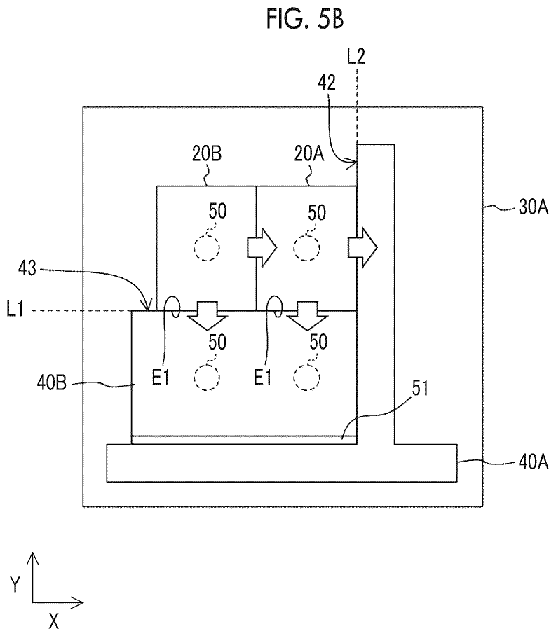

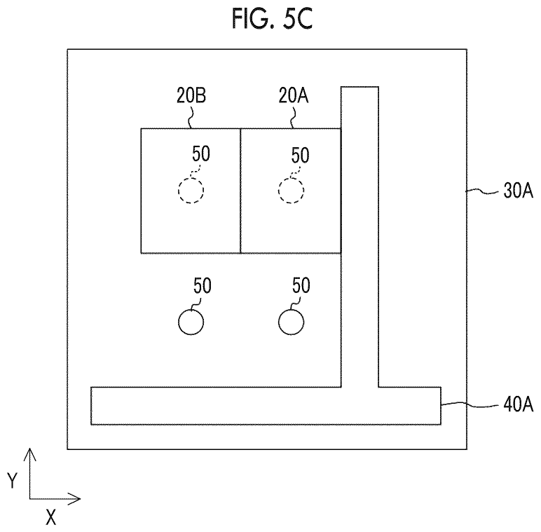

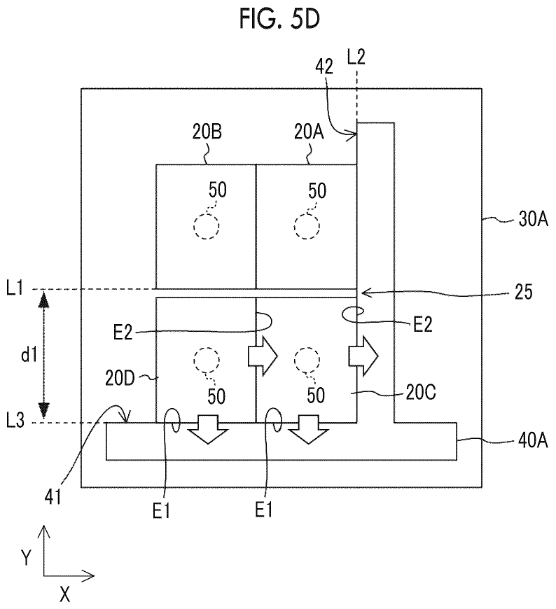

Here, in a case in which the reference plate 40A is moved in the direction of the side E2 (Y direction), there is a concern that the arranged detection elements may be moved by friction and the arrangement may be disrupted. FIGS. 5A, 5B, 5C, and 5D are plan views showing an example of a manufacturing method in which the movement of the arranged detection elements can be avoided.

The plurality of detection elements are arranged using the reference plate 40B and a spacer 51 in addition to the surface plate 30A and the reference plate 40A (FIG. 5A). The reference plate 40B is a rectangular ruler, in which a long side of the reference plate 40B is in contact with the side surface 41 of the reference plate 40A with the spacer 51 interposed therebetween, and a short side of the reference plate 40B is in contact with the side surface 42 of the reference plate 40A. The reference plate 40B has a side surface 43 that defines a straight line that extends in the X direction. In the present example, the straight line defined by the side surface 43 of the reference plate 40B is the first reference line L1, the straight line defined by the side surface 42 of the reference plate 40A is the second reference line L2, and the straight line defined by the side surface 41 of the reference plate 40A is the third reference line L3. The dimensions of the reference plate 40B and the spacer 51 in the Y direction are determined such that a distance between the first reference line L1 and the third reference line L3 is d1. A plurality of suction ports 50 for fixing the arranged detection elements onto the surface plate 30A by vacuum suction are provided on the surface of the surface plate 30A. The vacuum suction can be switched on and off for each suction port.

As shown in FIG. 5B, on the surface plate 30A, the side E1 of each of the detection elements 20A and 20B is brought into contact with the side surface 43 of the reference plate 40B. That is, the side E1 of each of the detection elements 20A and 20B is disposed on the first reference line L1. Further, the side E2 of the detection element 20A is brought into contact with the side surface 42 of the reference plate 40A. That is, the side E2 of the detection element 20A is disposed on the second reference line L2. Further, the side E2 of the detection element 20B is brought into contact with the detection element 20A. As a result, the detection elements 20A and 20B line up along the direction of the side E1 (X direction) in a state in which the sides E1 are aligned. The detection elements 20A and 20B are arranged on the surface plate 30A in the direction (that is, in a direction facing downward) in which the detection surface on which the radiation is incident is in contact with the surface of the surface plate 30A. Then, the vacuum suction is performed by the suction port 50 disposed directly below the detection elements 20A and 20B. As a result, the detection elements 20A and 20B are fixed onto the surface plate 30A, and the risk of the arrangement of the detection elements 20A and 20B being disordered is suppressed.

Next, as shown in FIG. 5C, the spacer 51 and the reference plate 40B are removed from the surface plate 30A in this order. The reference plate 40A is not moved and is maintained stationary on the surface plate 30A.

Next, as shown in FIG. 5D, the side E1 of each of the detection elements 20C and 20D is brought into contact with the side surface 41 of the reference plate 40A. That is, the side E1 of each of the detection elements 20C and 20D is disposed on the third reference line L3. Further, the side E2 of the detection element 20C is brought into contact with the side surface 42 of the reference plate 40A. That is, the side E2 of the detection element 20C is disposed on the second reference line L2. Further, the side E2 of the detection element 20D is brought into contact with the detection element 20C. As a result, the detection elements 20C and 20D line up along the direction of the side E1 (X direction) in a state in which the sides E1 are aligned. In addition, the detection element 20A and the detection element 20C line up along the direction of the side E2 (Y direction) in a state in which the sides E2 are aligned. The detection elements 20C and 20D are arranged on the surface plate 30A in a direction (that is, in a direction facing downward) in which the detection surface on which the radiation is incident is in contact with the surface of the surface plate 30A. Then, the vacuum suction is performed by the suction port 50 disposed directly below the detection elements 20C and 20D. As a result, the detection elements 20C and 20D are fixed onto the surface plate 30A, and the risk of the arrangement of the detection elements 20C and 20D being disordered is suppressed.

The distance between the sides E1 of the detection elements 20A and 20B and the sides E1 of the detection elements 20C and 20D is d1, and the gap 25 is formed between the detection elements 20A and 20B and the detection elements 20C and 20D. The dimension of the gap 25 is adjusted such that the distance between the sides E1 is d1. The dimensional error of the side E2 of each of the detection elements is absorbed by the gap 25.

As described above, by arranging the plurality of detection elements using the reference plate 40B and the spacer 51 in addition to the surface plate 30A and the reference plate 40A, it is not necessary to move the reference plate 40A. Accordingly, the movement of the arranged detection elements can be avoided. By using the vacuum suction in combination, the above-described effect can be promoted.

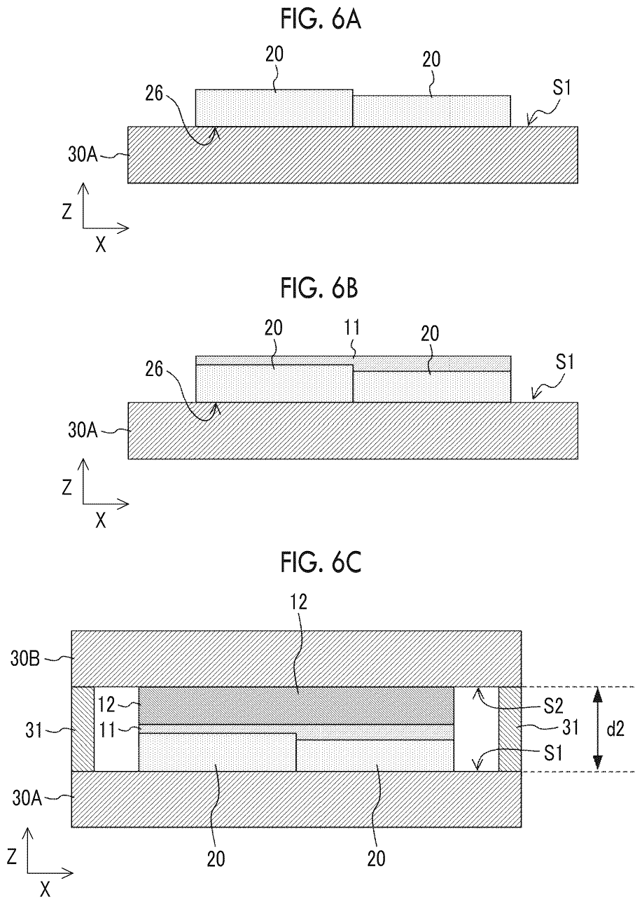

After the arrangement of the plurality of detection elements 20 on the surface plate 30A is completed, the plurality of detection elements 20 are joined to the fixed plate 12 in a state in which the relative positions thereof are maintained. FIGS. 6A, 6B, and 6C are views showing an example of steps of joining the plurality of detection elements 20 to the fixed plate 12.

As shown in FIG. 6A, the surface plate 30A is disposed on a lower side in a vertical direction with respect to the plurality of detection elements 20. The plurality of detection elements 20 are arranged on the surface plate 30A in a direction (that is, in a direction facing downward) in which the detection surface 26 on which the radiation is incident is in contact with the surface of the surface plate 30A. The surface of the surface plate 30A is a first reference surface S1. The plurality of detection elements 20 have a thickness variation due to the dimensional error in the thickness direction. Therefore, the plurality of detection elements 20 can be arranged on the surface plate 30A in a state in which the height positions of the back surfaces on a side opposite to the detection surfaces 26 are not aligned.

Next, as shown in FIG. 6B, the adhesive 11 is applied to the back surface of each of the plurality of detection elements 20 on a side opposite to the detection surface 26. The adhesive 11 may be, for example, an adhesive made of an epoxy resin. The adhesive 11 spreads to fill a level difference caused by a variation in height positions of the back surfaces of the plurality of detection elements 20 due to the fluidity.

Next, as shown in FIG. 6C, the fixed plate 12 is placed on a surface of the adhesive 11. It is preferable that the fixed plate 12 has rigidity equal to or higher than a certain level. Therefore, it is preferable that the material of the fixed plate 12 is determined in consideration of the rigidity. Further, it is preferable that the fixed plate 12 has high thermal conductivity in order to promote the diffusion of heat generated by the absorption of radiation by each detection element 20. Therefore, it is preferable that the material of the fixed plate 12 is determined in consideration of the thermal conductivity. For example, the fixed plate 12 may be made of a material such as metal or synthetic resin. Subsequently, the surface plate 30B is placed on the surface of the fixed plate 12 on a side opposite to the surface in contact with the adhesive 11. The contact surface of the surface plate 30B with the fixed plate 12 is a second reference surface S2. The first reference surface S1 and the second reference surface S2 are maintained in parallel by the spacer 31 provided between the reference plate 40A and the reference plate 40B, and a distance between these surfaces is fixed to a predetermined distance d2. A laminate including the plurality of detection elements 20, the adhesive 11, and the fixed plate 12 is interposed between the first reference surface S1 defined by the surface plate 30A and the second reference surface S2 defined by the surface plate 30B. Then, the adhesive 11 is cured by leaving the plurality of detection elements 20 and the fixed plate 12 at room temperature in a state in which the relative positions of the plurality of detection elements 20 and the fixed plate 12 are maintained. By going through each of the above-described steps, the radiation detector 10 is completed.

Since each of the plurality of detection elements 20 is joined to the fixed plate 12 in a state in which the detection surface 26 is in contact with the first reference surface S1 defined by the surface plate 30A, it is possible to extend the respective detection surfaces 26 of the plurality of detection elements 20 in the same plane (that is, to align the height positions of the detection surfaces 26). The thickness variation of the plurality of detection elements 20 is absorbed by the adhesive 11. Accordingly, the adhesive 11 has the thickness profile in accordance with the thickness variation of the plurality of detection elements 20.

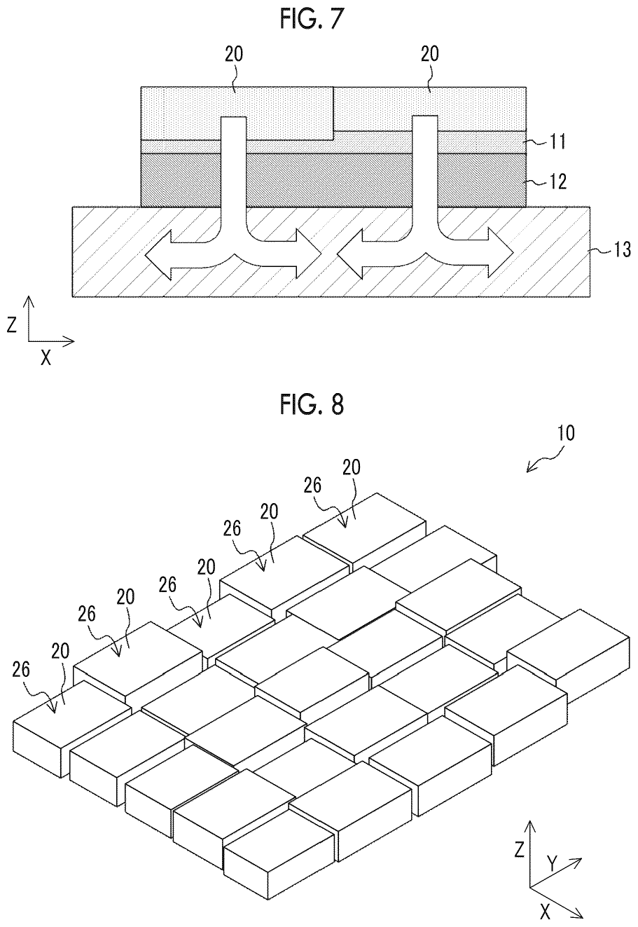

As shown in FIG. 7, the fixed plate 12 may be joined to a base plate 13 having a large heat capacity. The heat generated by each detection element 20 by absorbing the radiation is diffused to the base plate 13 via the adhesive 11 and the fixed plate 12. As the thickness of the adhesive 11 increases, an absorption width of the thickness variation of the detection element 20 can be increased, but the thermal conductivity is reduced. For this reason, it is preferable that the thickness of the adhesive 11 is determined in consideration of both the absorption of the thickness variation of the detection element 20 and the thermal conductivity. For example, the type and the thickness of the adhesive 11 may be determined such that a ratio C/T of thermal conductivity C of the adhesive 11 to a thickness T of the adhesive 11 is equal to or greater than a predetermined threshold value. As a result, it is possible to avoid a significant decrease in either the absorption of the thickness variation of the detection element 20 or the thermal conductivity. As the thickness T of the adhesive 11, for example, a thickness of a thickest portion, a thickness of a thinnest portion, or an intermediate thickness thereof may be applied.

As described above, the detection elements 20 are manufactured with the dimensional errors in the plane direction and the thickness direction. Therefore, as shown in FIG. 8, in a case in which the plurality of detection elements 20 are simply arranged, the dimensional errors are accumulated, and there is a concern that the image quality of the radiation image captured using the radiation detector is deteriorated. In addition, the height positions of the detection surfaces 26 on which the radiation is incident become uneven, which may result in the deterioration of the image quality of the radiation image.

With the manufacturing method of the radiation detector 10 according to the present embodiment, the plurality of detection elements 20 are arranged such that the plurality of detection elements 20 line up along the direction of the side E1 (X direction) and the direction of the side E2 (Y direction), and the gap 25 is formed between the detection elements 20 that line up along the direction of the side E2 (Y direction). The dimension of the gap 25 is adjusted such that a distance between the sides E1 of the detection elements 20 that line up along the direction of the side E2 (Y direction) is a predetermined distance d1.

With the manufacturing method according to the present embodiment, the dimensional error of the side E2 is absorbed by the gap 25. Accordingly, it is possible to avoid the accumulation of the dimensional errors in the direction of the side E2 (Y direction) of the detection element 20. In addition, since the number of arranged detection elements 20 in the direction of the side E1 (X direction) is small, the cumulative dimension errors of the side E1 are acceptable.

In addition, the manufacturing method of the radiation detector 10 according to the present embodiment includes joining, in a state in which the detection surface 26, on which the radiation is incident, of each of the plurality of detection elements 20 is in contact with the first reference surface S1, the back surface of each of the plurality of detection elements 20 on a side opposite to the detection surface 26 to the fixed plate 12 via the adhesive 11. The adhesive 11 has a thickness profile in accordance with the thickness variation of the plurality of detection elements 20.

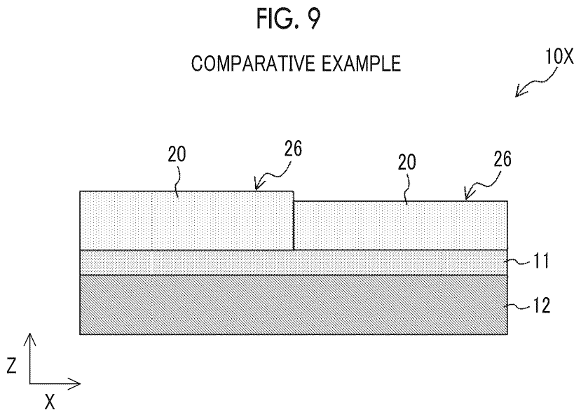

Here, FIG. 9 is a cross-sectional view showing an example of a configuration of a radiation detector 10X according to a comparative example. The radiation detector 10X according to the comparative example is manufactured by a procedure of applying the adhesive 11 to the surface of the fixed plate 12 and placing the plurality of detection elements 20 on the surface of the adhesive 11 in a state in which the detection surface 26 faces upward. With this manufacturing method, the height positions of the detection surfaces 26 become uneven due to the thickness variation of the plurality of detection elements 20, and there is a concern that the image quality of the radiation image captured using the radiation detector 10X may be deteriorated.

Meanwhile, with the manufacturing method of the radiation detector 10 according to the embodiment of the technology of the present disclosure, each of the plurality of detection elements 20 is joined to the fixed plate 12 in a state in which the detection surface 26 is in contact with the first reference surface S1 defined by the surface plate 30A, and thus the detection surfaces 26 of the plurality of detection elements 20 can be extended in the same plane (that is, the height positions of the detection surfaces 26 can be aligned).

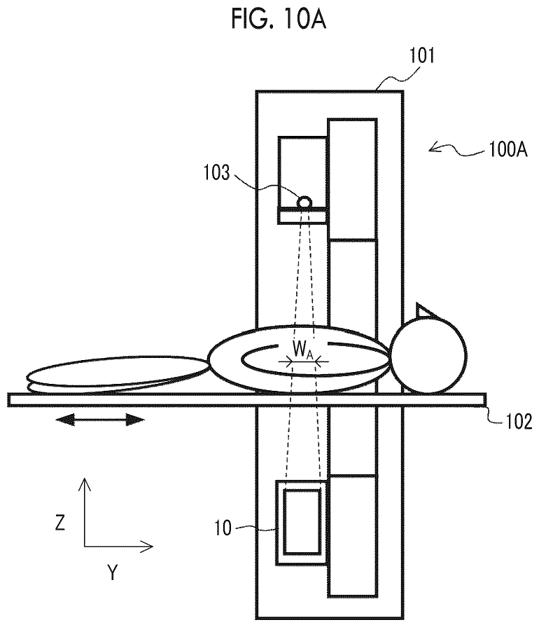

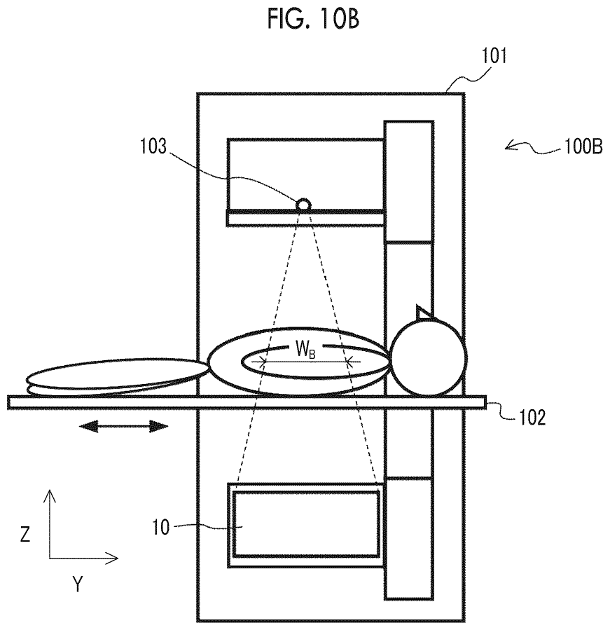

The radiation detector 10 according to the embodiment of the technology of the present disclosure can be applied to, for example, a computed tomography (CT) apparatus. In the CT apparatus, an area of the radiation detector is increasing. FIG. 10A is a cross-sectional view schematically showing an example of a configuration of a typical CT apparatus 100A including the radiation detector 10 with a normal area. FIG. 10B is a cross-sectional view schematically showing an example of a configuration of a wide detector (WD) CT apparatus 100B including the radiation detector 10 with a large area.

Each of the typical CT apparatus 100A and the WDCT apparatus 100B includes the radiation detector 10, an examination table 102, and a radiation source (radiation tube) 103. The radiation source 103 and the radiation detector 10 are accommodated inside an annular gantry 101. The examination table 102 can slide toward the inside of the gantry 101. The radiation source 103 and the radiation detector 10 can continuously capture the radiation images (projection images) while rotating along a peripheral surface of the gantry 101. A tomographic image is obtained by reconstructing a plurality of radiation images captured in different imaging directions. An imaging width WA in the typical CT apparatus 100A is, for example, 4 cm, and an imaging width WB in the WDCT apparatus 100B is, for example, 16 cm. With the WDCT apparatus 100B, since a moving organ such as the heart can be imaged in only one rotation, a clear radiation image can be obtained. Since the radiation detector 10 according to the embodiment of the technology of the present disclosure is configured by combining the plurality of detection elements 20, the increase in area of the radiation detector 10 can be handled, and the radiation detector 10 can be applied to the WDCT apparatus 100B.

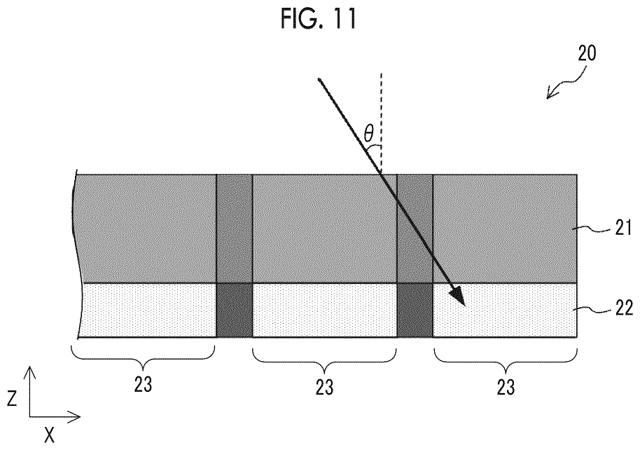

In the WDCT apparatus 100B, overlapping incidence of the radiation may occur due to a large (elongated) area of the radiation detector 10. An incidence angle θ of the radiation emitted from the radiation source to the radiation detector 10 is increased toward an end portion of the radiation detector 10. The increase in the incidence angle θ is more remarkable at the end portion of the radiation detector 10 having a large (elongated) area. As shown in FIG. 11, at the end portion of the radiation detector 10 having a large (elongated) area, the incidence angle θ of the radiation is increased to an extent that the overlapping incidence of the radiation incident on both of two pixels 23 adjacent to each other may occur. The overlapping incidence of the radiation causes the deterioration of the image quality of the radiation image captured using the radiation detector 10.

In order to avoid the overlapping incidence of the radiation, it is considered to change the direction of the detection surface of the radiation detector in accordance with the incidence position of the radiation. That is, in the radiation detector, by forming a multi-surface structure bent in at least one place in one direction, it is possible to avoid the overlapping incidence of the radiation.

FIG. 12 is a perspective view of a radiation detector 10A having a three-surface structure according to the embodiment of the technology of the present disclosure. The radiation detector 10A has a first surface 27A, a second surface 27B, and a third surface 27C on which the detection surfaces 26 face in different directions. The first surface 27A and the third surface 27C disposed at one end and the other end in the Y direction are each composed of the detection surfaces 26 of four detection elements 20 in a 2×2 arrangement. The second surface 27B disposed in the center in the Y direction is composed of the detection surfaces 26 of eight detection elements 20 in a 2×4 arrangement.

In a case in which the radiation detector 10A having the three-surface structure is applied to the WDCT apparatus 100B, the direction of the side E1 (X direction) of the detection element 20 corresponds to a rotation direction of the radiation detector, and the direction of the side E2 (Y direction) of the detection element 20 corresponds to a slide direction (body axis direction of the subject) of the examination table 102.

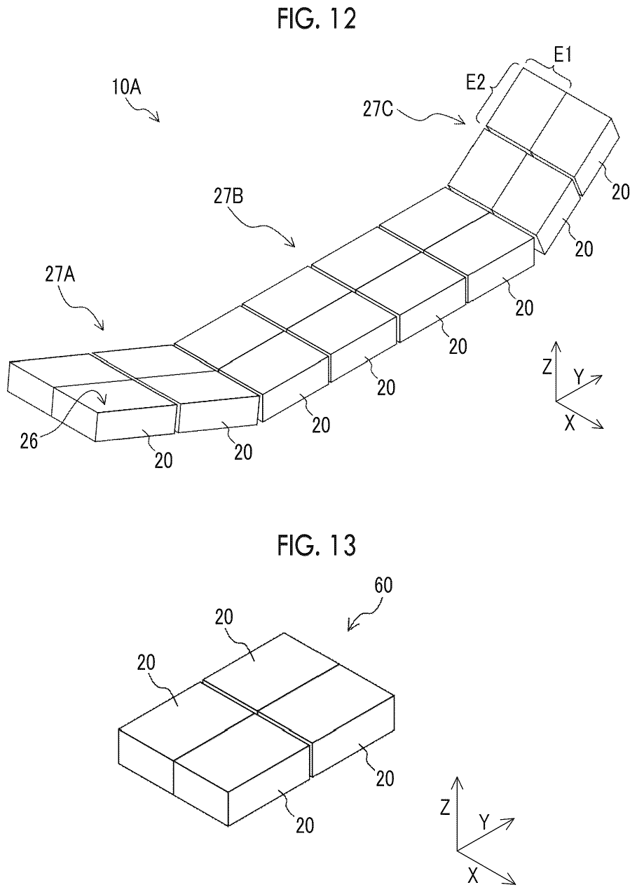

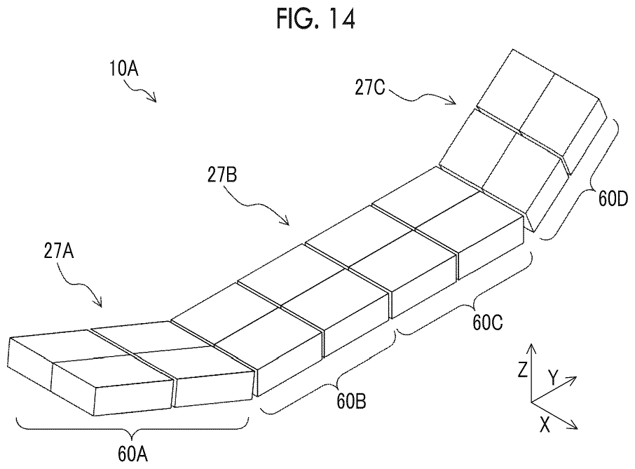

The radiation detector 10A having a three-surface structure may be manufactured by combining, for example, units 60 formed of four detection elements 20 in a 2×2 arrangement as shown in FIG. 13. That is, four units 60 are created in advance, and these units are connected to each other to complete the radiation detector 10A having the three-surface structure. The direction of the detection surface 26 differs for each unit. As shown in FIG. 14, the first surface 27A is formed by a first unit 60A, the second surface 27B is formed by a second unit 60B and a third unit 60C, and the third surface 27C is formed by a fourth unit 60D. The unit 60 consisting of the four detection elements 20 in a 2×2 arrangement can be manufactured by the methods shown in FIGS. 4A to 4D, FIGS. 5A to 5D, and FIGS. 6A to 6C.

In regard to the above embodiment, the following supplementary notes will be further disclosed.

### Supplementary Note 1

A manufacturing method of a radiation detector including a plurality of detection elements each including a plurality of pixels for detecting radiation, the manufacturing method comprising: joining, in a state in which a detection surface, on which radiation is incident, of each of the plurality of detection elements is in contact with a first reference surface, a back surface of each of the plurality of detection elements on a side opposite to the detection surface to a fixed plate via an adhesive.

### Supplementary Note 2

The manufacturing method according to supplementary note 1, in which the adhesive has a thickness profile in accordance with a thickness variation of the plurality of detection elements.

### Supplementary Note 3

The manufacturing method according to supplementary note 1 or 2, in which a laminate including the plurality of detection elements, the adhesive, and the fixed plate is interposed between the first reference surface and a second reference surface of which a distance from the first reference surface is fixed.

### Supplementary Note 4

The manufacturing method according to any one of supplementary notes 1 to 3, in which the first reference surface is brought into contact with the detection surfaces, which face downward in a vertical direction, of the plurality of detection elements.

### Supplementary Note 5

The manufacturing method according to any one of supplementary notes 1 to 4, in which each of the plurality of detection elements has a first side and a second side intersecting the first side, and the plurality of detection elements that line up along a direction of the first side and a direction of the second side are joined to the fixed plate.

### Supplementary Note 6

The manufacturing method according to any one of supplementary notes 1 to 5, in which a ratio C/T of thermal conductivity C of the adhesive to a thickness T of the adhesive is equal to or greater than a threshold value.

### Supplementary Note 7

The manufacturing method according to any one of supplementary notes 1 to 6, in which the plurality of detection elements form a unit, and a plurality of the units are combined.

### Supplementary Note 8

The manufacturing method according to supplementary note 7, in which a direction of the detection surface differs for each unit.

### Supplementary Note 9

The manufacturing method according to any one of supplementary notes 1 to 8, in which a material of the fixed plate is determined in consideration of rigidity.

### Supplementary Note 10

The manufacturing method according to any one of supplementary notes 1 to 9, in which a material of the fixed plate is determined in consideration of thermal conductivity.

### Supplementary Note 11

A radiation detector comprising: a plurality of detection elements each including a plurality of pixels for detecting radiation; and a fixed plate joined to back surfaces of the plurality of detection elements on a side opposite to detection surfaces on which the radiation is incident, via an adhesive, in which the detection surface of each of the plurality of detection elements extends in the same plane.

### Supplementary Note 12

The radiation detector according to supplementary note 11, in which the adhesive has a thickness profile in accordance with a thickness variation of the plurality of detection elements.

What is claimed is:

1. A manufacturing method of a radiation detector including a plurality of detection elements each including a plurality of pixels for detecting radiation, the manufacturing method comprising:
joining a back surface of each of the plurality of detection elements, the back surface is a side opposite to a detection surface on which radiation is incident, to a fixed plate via an adhesive in a state in which the detection surface of each of the plurality of detection elements is in contact with a first reference surface.

2. The manufacturing method according to claim 1,
wherein the adhesive has a thickness profile in accordance with a thickness variation of the plurality of detection elements.

3. The manufacturing method according to claim 1,
wherein a laminate including the plurality of detection elements, the adhesive, and the fixed plate is interposed between the first reference surface and a second reference surface of which a distance from the first reference surface is fixed.

4. The manufacturing method according to claim 1,
wherein the first reference surface is brought into contact with the detection surfaces, which face downward in a vertical direction, of the plurality of detection elements.

5. The manufacturing method according to claim 1,
wherein each of the plurality of detection elements has a first side and a second side intersecting the first side, and
the plurality of detection elements that line up along a direction of the first side and a direction of the second side are joined to the fixed plate.

6. The manufacturing method according to claim 1,
wherein a ratio C/T of thermal conductivity C of the adhesive to a thickness T of the adhesive is equal to or greater than a threshold value.

7. The manufacturing method according to claim 1,
wherein the plurality of detection elements form a unit, and a plurality of the units are combined.

8. The manufacturing method according to claim 7,
wherein a direction of the detection surface differs for each unit.

9. The manufacturing method according to claim 1,
wherein a material of the fixed plate is determined in consideration of rigidity.

10. The manufacturing method according to claim 1,
wherein a material of the fixed plate is determined in consideration of thermal conductivity.

11. A radiation detector comprising:
a plurality of detection elements each including a plurality of pixels for detecting radiation; and
a fixed plate joined to back surfaces of the plurality of detection elements on a side opposite to detection surfaces on which the radiation is incident, via an adhesive,
wherein the detection surface of each of the plurality of detection elements is configured to be in the same plane.

12. The radiation detector according to claim 11,
wherein the adhesive has a thickness profile in accordance with a thickness variation of the plurality of detection elements.
